(19) United States
(12) Patent Application Publication
(10) Pub. No.: US 2024/0411971 A1
(43) Pub. Date: Dec. 12, 2024

(54) METHODS OF MANUFACTURING SEMICONDUCTOR DEVICES AND METHODS OF VERIFYING LAYOUTS OF MASK ROMS

(71) Applicant: Samsung Electronics Co., Ltd., Suwon-si (KR)

(72) Inventor: Chanho Lee, Suwon-si (KR)

(21) Appl. No.: 18/625,456

(22) Filed: Apr. 3, 2024

(30) Foreign Application Priority Data
Jun. 9, 2023 (KR) 10-2023-0074363
Aug. 14, 2023 (KR) 10-2023-0106117

(51) Int. Cl. G06F 30/33; G06F 30/327

(52) U.S. Cl. CPC G06F 30/33; G06F 30/327

(57) ABSTRACT

A method of manufacturing a semiconductor device includes generating a target check code by performing target code generation computation on a target ROM code; generating first netlist data and first layout data of a semiconductor device including a mask ROM storing the target ROM code; inserting the target check code into the first netlist data; performing layout-versus-schematic (LVS) verification of the first netlist data and the first layout data, resulting in verified first netlist data; generating a final check code by performing the target code generation computation on a final ROM code of the mask ROM; determining whether the target check code stored in the first netlist data for which the LVS verification has been completed matches the final check code; and performing a mask tape-out operation (MTO) of the first layout data when the target check code matches the final check code.

### CROSS-REFERENCE TO RELATED APPLICATIONS

This application claims benefit of priority to Korean Patent Application No. 10-2023-0074363 filed on Jun. 9, 2023, in the Korean Intellectual Property office, and to Korean Patent Application No. 10-2023-0106117 filed on Aug. 14, 2023, in the Korean Intellectual Property Office, and the entire contents of the above-identified applications are incorporated by reference herein.

### BACKGROUND

Aspects of the present disclosure relate to methods of manufacturing semiconductor devices and methods of verifying layouts of mask ROMs.

A read-only memory (ROM) may be a device storing data non-volatilely, and stored data may not be lost even when power supplied to the ROM is turned off or disconnected. Among the various types of ROM, a mask ROM (MROM) may allow data to be programmed by semiconductor manufacturers. For example, a mask ROM may store data by forming a predetermined circuit pattern on a semiconductor, and generally, a predetermined circuit pattern may be formed using a photo mask manufactured to correspond to data to be stored in the mask ROM.

A mask ROM may be included in various semiconductor devices due to a relatively simpler structure than other types of semiconductor memory structures. For example, a microprocessor may include a mask ROM to store a microcode, and a microcontroller may include a mask ROM to store a bootloader or firmware. When there is an error in data stored in a mask ROM, that is, when there is an error in a ROM code, the costs to correct the error may be relatively high.

### SUMMARY

Some aspects of the present disclosure provide a method of verifying more easily whether a layout of a mask ROM conforms to a ROM code without analyzing the layout of the mask ROM.

According to an example embodiment of the present disclosure, a method of manufacturing a semiconductor device includes generating a target check code by performing target code generation computation on a target ROM code; generating first netlist data and first layout data of a semiconductor device including a mask ROM storing the target ROM code; inserting the target check code into the first netlist data; performing layout-versus-schematic (LVS) verification of the first netlist data and the first layout data, resulting in verified first netlist data; generating a final check code by performing the target code generation computation on a final ROM code of the mask ROM; determining whether the target check code stored in the verified first netlist data matches the final check code; and performing a mask tape-out operation (MTO) of the first layout data when the target check code matches the final check code.

According to some example embodiments of the present disclosure, a method of manufacturing a semiconductor device includes generating a target check code by performing target code generation computation on a target ROM code; generating first netlist data and first layout data of a semiconductor device including a mask ROM storing the target ROM code; inserting the target check code into a text region included in the first layout data; generating a final check code by receiving a final ROM code of the mask ROM and performing the target code generation computation on the final ROM code; determining whether the target check code inserted in the first layout data matches the final check code; and performing a mask tape-out (MTO) operation on the first layout data when the target check code matches the final check code.

According to some example embodiments of the present disclosure, a method of verifying a layout of a mask ROM may include: inserting a check code generated by performing check code generation computation on a ROM code of the mask ROM into netlist data of the mask ROM; performing LVS verification on the netlist data and layout data of the mask ROM; and comparing a final check code generated by performing a check code computation on a final ROM code to be stored in the mask ROM with the check code inserted into the netlist data.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a diagram illustrating a method of manufacturing a semiconductor device according to some example embodiments of the present disclosure;

FIG. 2 is a diagram illustrating a ROM code of a mask ROM according to some example embodiments of the present disclosure;

FIG. 3 is a diagram illustrating a structure of a cell array included in a mask ROM according to some example embodiments of the present disclosure;

FIG. 4 is a diagram illustrating a netlist data of mask ROM according to some example embodiments of the present disclosure;

FIG. 5A is a diagram illustrating layout data of a mask ROM according to some example embodiments of the present disclosure;

FIG. 5B is a diagram illustrating a mask ROM according to some example embodiments of the present disclosure;

FIG. 6 is a flowchart illustrating a method of manufacturing a semiconductor device according to some example embodiments of the present disclosure;

FIG. 7 is a diagram illustrating a method of generating a check code according to some example embodiments of the present disclosure;

FIG. 8A is a diagram illustrating netlist data into which a check code is inserted according to some example embodiments of the present disclosure;

FIG. 8B is a diagram illustrating layout data into which a check code is inserted according to some example embodiments of the present disclosure;

FIG. 9 is a flowchart illustrating a method of manufacturing a semiconductor device according to some example embodiments of the present disclosure;

FIG. 10 is a diagram illustrating a storage medium according to some example embodiments of the present disclosure; and

FIG. 11 is a diagram illustrating a computer system according to some example embodiments of the present disclosure.

### DETAILED DESCRIPTION

Hereinafter, some examples of embodiments of the present disclosure will be described as follows with reference to the accompanying drawings.

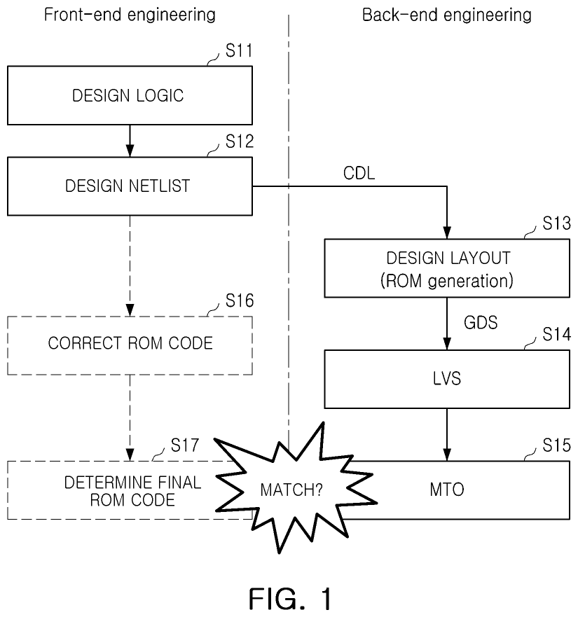

FIG. 1 is a diagram illustrating a method of manufacturing a semiconductor device according to some example embodiments.

To manufacture a semiconductor device, a mask including layout patterns to be transferred to a semiconductor substrate such as a wafer may be manufactured. The process of designing layout patterns formed on a mask may largely include front-end designing and back-end designing.

The front-end designing may include operation S11 and operation S12. In operation S11, a function and an architecture of the semiconductor device may be defined, and operation of the digital circuit may be defined in register-transfer level (RTL) using a hardware description language (HDL) such as VHDL or Verilog.

In operation S12, a gate level netlist data may be generated by synthesizing input data defined in the RTL using a standard cell library. That is, the netlist data may correspond to a schematic data. For example, operation S12 may be performed by a processor using a synthesis tool. The netlist data may have a circuit description language (CDL) format.

The back-end designing may include operation S13 to operation S15. In operation S13, layout data of the semiconductor device may be generated by placing and routing (P&R) standard cells included in the semiconductor device according to the netlist. For example, operation S13 may be performed by a processor using a layout design tool, and the layout data may have a format such as a graphic design system (GDS) or GDSII.

In operation S14, layout-versus-schematic (LVS) verification of the semiconductor device may be performed. Specifically, by performing a design rule check (DRC) operation on the layout data, a connection relationship between polygons may be automatically detected from the layout data, and whether the netlist data matches the layout data may be verified using the detected connection relationship. Operation S14 may be performed by the processor using a LVS verification tool.

In operation S15, a mask tape-out (MTO) operation may be performed on the layout data. MTO may refer to requesting manufacturing of a mask by providing, to a foundry, layout data on which layout verification, such as LVS verification, has been completed.

The semiconductor device may include at least a portion of a mask ROM. A mask ROM may store data using a circuit pattern formed on a semiconductor substrate. For example, the layout design tool may include a memory generator. The memory generator may receive a ROM code, which is data to be stored in the mask ROM, and may perform ROM generation in relation to the layout data of the mask ROM reflecting the ROM code by referring to the cell library.

The ROM code may be developed and/or corrected even during back-end designing. For example, firmware of the semiconductor device may be stored as a ROM code in the mask ROM. To shorten the production period of semiconductor devices, the back-end designing may be performed using an arbitrary ROM code before the firmware development is completed. While the back-end designing is performed, development of firmware of the semiconductor device may be performed in operation S16, and the final ROM code may be determined in operation S17. Also, the layout data of the semiconductor device may be corrected such that the mask ROM may store the final ROM code.

When the MTO operation is performed on the layout data not reflecting the final ROM code, the costs to correct the error may increase. For example, the cost of discarding a mask including an error may be higher than the cost of correcting layout data including an error. Accordingly, before the MTO operation is performed on the layout data, it may be highly desirable to verify whether the final ROM code matches the ROM code reflected in the layout data.

To verify whether the ROM codes match, a method of verifying whether each bit included in the final ROM code is reflected in the layout data by analyzing the layout patterns included in the layout data using a layout design tool may be considered. However, in the case of verification method using a layout design tool, versatility may be reduced depending on the type or version of the layout design tool.

In the description below, a method of verifying whether the final ROM code is reflected in the MTO layout data without using a specific layout design tool may be suggested.

In some example embodiments, when generating layout data, a check code may be generated on the basis of the ROM code reflected in the layout data. The check code may be written in the generated layout data or the netlist data corresponding to the layout data in a text format which may be decoded without using a layout design tool.

Before the layout data is mask taped-out, a final check code may be generated on the basis of the final ROM code. By comparing the check code written in the layout data or the netlist data and the final check code, a consistency between the final ROM code and the ROM code reflected in the layout data which is mask taped-out may be verified.

In some example embodiments, the layout of the mask ROM may be verified without using a layout design tool, such that versatility of layout verification may be improved. Also, since the operation of analyzing layout patterns in a bit unit may not be performed, the time required for the verification may be shortened.

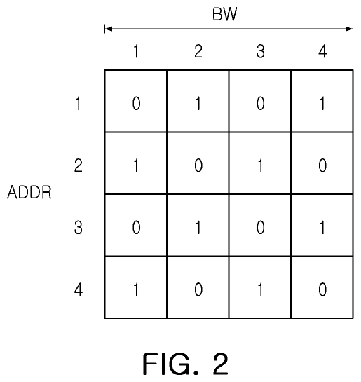

In the description below, a method of verifying the layout of a mask ROM according to an example embodiment will be described in greater detail with reference to FIGS. 2 to 10.

FIG. 2 is a diagram illustrating a ROM code of a mask ROM according to some example embodiments.

The mask ROM may store a ROM code including a plurality of words having a specified word bandwidth (BW). The ROM code may be a binary code and may be the result of compiling source codes such as firmware of a semiconductor device. FIG. 2 illustrates an example in which a ROM code including 4 words having a bandwidth of 4 bits is aligned according to the address ADDR of the word.

The schematic data and the layout of the mask ROM may be determined on the basis of the structure of the mask ROM, such as a bandwidth of the word and the number of words, and the ROM code.

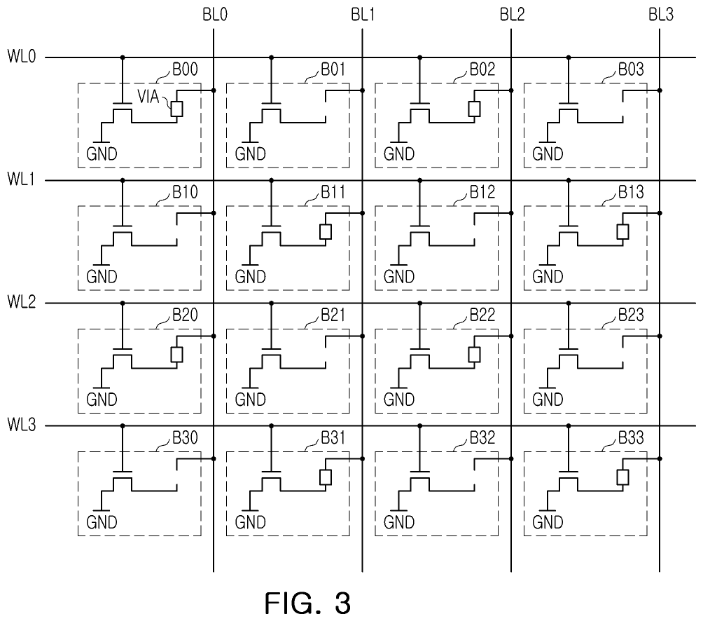

FIG. 3 is a diagram illustrating a structure of a cell array included in a mask ROM according to some example embodiments.

The mask ROM may include a cell array including a plurality of memory cells, a driver for accessing each memory cell, a sense amplifier for sensing signals output by the memory cell, and a register. FIG. 3 illustrates a portion of the schematic diagram of the mask ROM corresponding to the structure and the ROM code of the mask ROM illustrated in FIG. 2, and illustrates the structure of the cell array included in the mask ROM.

A cell array 100 may include a plurality of memory cells B00-B33. Each of the plurality of memory cells B00-B33 may be connected to one of the word lines WL0-WL3 and may include a transistor, the transistor having a gate that is connected to the word line and a source that is connected to the ground voltage GND. The bits stored by the memory cells connected to a single word line may form a single word.

The memory cell of the mask ROM may store bits depending on the presence or absence or arrangement of a bit decision portion. The bit decision portion may include at least one type of material, may refer to a portion having a volume on the semiconductor substrate, and may include at least one of a via, a metal, a diffusion region, an injection region, and a contact region. In the example in FIG. 3, the bit decision portion may be configured as a via, and may store different bits depending on the presence or absence of the via.

Each of the plurality of cells B00-B33 may selectively include a via VIA. A transistor of the memory cells including the via VIA may be connected to one of the bitlines BL0-BL3 through the via VIA.

Each of the plurality of memory cells B00-B33 may store bits depending on the presence or absence of the via VIA. For example, each of bitlines BL0-BL3 may be connected to a pull-up resistor connected to a supply voltage. The memory cell B00 may include a transistor connected to the bitline BL0 through the via VIA, and when word line WL0 is activated, the voltage of bitline BL0 may approximately become a ground voltage by the transistor included in the memory cell B00 and the via V00.

The memory cell B01 may not include a via, and accordingly, the transistor included in the memory cell B01 may not be connected to the bitline BL1. Accordingly, regardless of whether the word line WL0 is activated, the bitline BL1 may approximately maintain the power supply voltage by the pull-up resistor. A circuit such as a sense amplifier connected to the bitlines BL0-BL3 may sense data stored in the memory cells B00-B03 connected to the activated word line WL0 by detecting the voltage of the bitlines BL0-BL3 when the word line WL0 is activated.

The netlist data for writing the schematic diagram illustrated in FIG. 3 may be generated. For example, the netlist data of the mask ROM may define the input/output and physical dimensions of the transistors included in the memory cells B00-B33, and may further define the output pins and the power supply of the mask ROM.

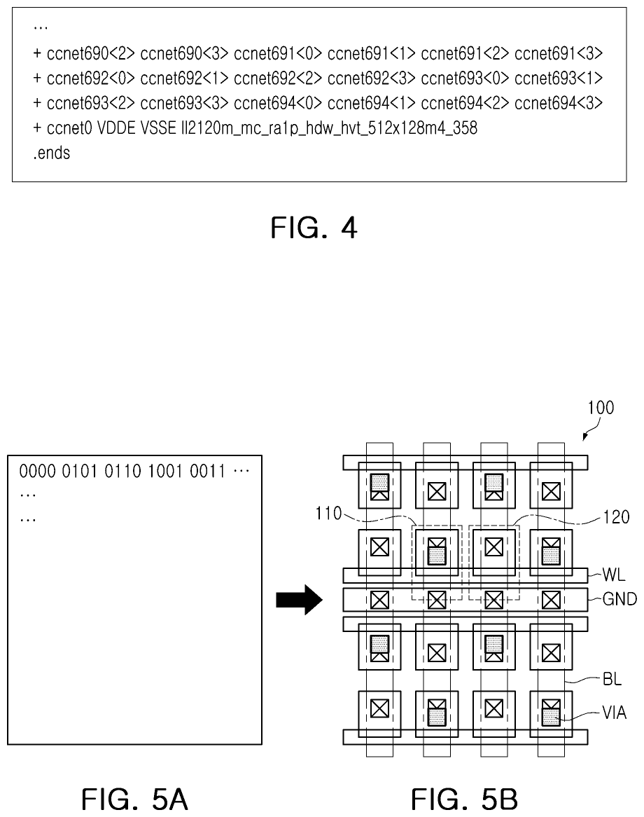

FIG. 4 is a diagram illustrating a netlist data of mask ROM according to some example embodiments.

FIG. 4 illustrates a portion of netlist data. The netlist data of the mask ROM may be provided as a text file decoded by humans. For example, the netlist data may be provided as a file having a circuit description language (CDL) format. Since the netlist data is provided as a text file, the netlist data may be decoded and corrected without using a dedicated tool for semiconductor design.

Layout data may be provided in a binary format, and it may not be easy (or relatively easy) to decode or correct without using a layout design tool.

FIG. 5A is a diagram illustrating layout data of a mask ROM according to some example embodiments.

Referring to FIG. 5A, the layout data of the mask ROM may include sequences of “0” and “1” and may not be decoded by humans (or decoded by humans practically). For example, the layout data may be provided as a binary file having a format such as GDS, GDSII, or the like. Using a layout design tool, the layout data of the mask ROM may be displayed as a layout which may be interpreted by humans.

Referring to FIG. 5B, the layout of the mask ROM may include a plurality of word lines WL and a ground line GND extending in the horizontal direction, and a plurality of bitlines BL extending in the vertical direction. Also, in the layout of the mask ROM, a source may be connected to the ground line GND, a word line WL may form a gate, and a transistor selectively connected to the bitline BL through the via VIA may appear.

By analyzing the pattern of memory cells in the layout of the mask ROM, the ROM code stored in the mask ROM may be determined. Specifically, the data stored in the memory cell may be determined by analyzing the presence or absence of the via VIA connected to the transistor included in the memory cell. For example, a cell including a via VIA, such as a memory cell 110, may be referred to as an on-cell, and a cell not including a via VIA, such as a memory cell 120, may be referred to as an off-cell. The on-cell and the off-cell may store bits “0” and “1,” or “1” and “0,” respectively.

In the case of analyzing the layout of the mask ROM to verify whether the ROM code stored in the layout of the mask ROM matches the final ROM code, the verification may be difficult without using a layout design tool. Also, when using a verification tool involving analysis of the layout provided by the layout design tool for the verification, versatility of the verification tool may be reduced depending on the type or version of the layout design tool.

In the description below, a method of verifying whether the stored ROM code matches the final ROM code without analyzing the layout of the mask ROM using a layout design tool during the manufacturing process of a semiconductor device will be described in greater detail.

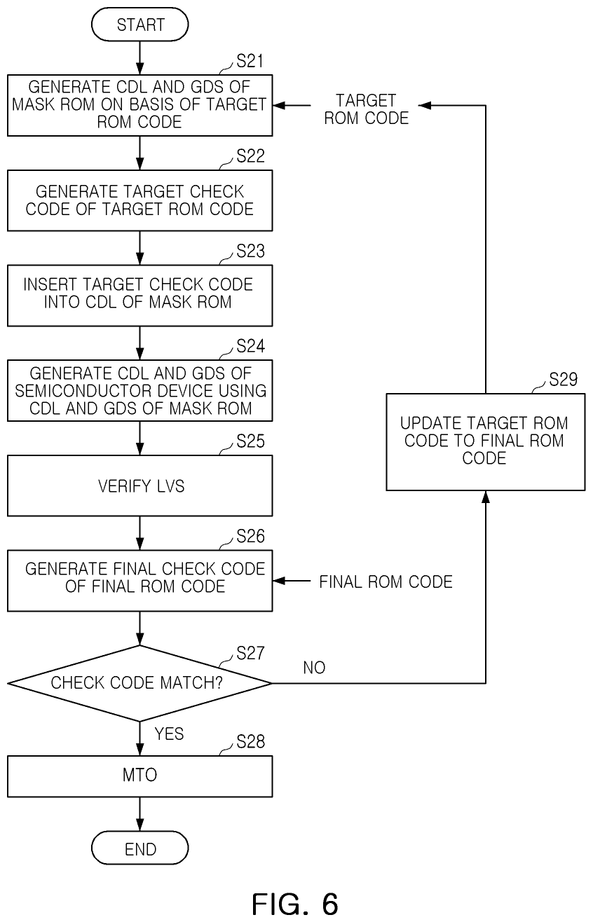

FIG. 6 is a flowchart illustrating a method of manufacturing a semiconductor device according to some example embodiments.

In operation S21, netlist data CDL and layout data GDS of the mask ROM may be generated using a target ROM code, which may be a ROM code to be stored in the mask ROM. Operation S21 may be performed by a processor using a memory generator.

In operation S22, a target check code may be generated by performing check code generation computation on the target ROM code. The check code generation computation may refer to computation of mapping the target ROM code to a target check code, which may be similar to hash computation. The check code generation computation may output the same check code for the same ROM code.

In operation S23, the target check code may be inserted into the netlist data CDL of the mask ROM. As described with reference to FIG. 4, the netlist data CDL may be corrected without using a specific layout design tool, and the target check code may be inserted into a designated region of the netlist data CDL.

In operation S24, the layout data GDS of the semiconductor device may be generated using the layout data GDS of the mask ROM. For example, as a portion of the layout data GDS of the semiconductor device, the layout data GDS of the mask ROM generated in operation S21 may be included.

The netlist data CDL of the semiconductor device may be generated on the basis of the netlist data CDL of the mask ROM. For example, the netlist data CDL of the mask ROM may be included as a portion of the netlist data CDL of the semiconductor device. The netlist data CDL of the semiconductor device may further include a target check code inserted into the netlist data CDL of the mask ROM.

In operation S25, LVS verification may be performed by comparing the netlist data CDL of the semiconductor device with the layout data GDS of the semiconductor device. Successful LVS verification may indicate that the layout data GDS of the semiconductor device accurately reflects the netlist data CDL of the semiconductor device.

In operation S26, a final check code mapped to the final ROM code to be stored in the mask ROM may be generated. For example, a final check code may be generated by receiving a final ROM code from a customer who supplies a semiconductor device and performing the check code generation computation on the final ROM code.

In operation S27, it may be determined whether the target check code included in the netlist data CDL of the semiconductor device matches the final check code.

When the target check code matches the final check code, the target ROM code matching the final ROM code may be reflected in the netlist data CDL of the semiconductor device. Since the layout data GDS for which LVS verification has been completed may accurately reflect the netlist data CDL, it may be verified that the layout data GDS reflects the target ROM code matching the final ROM code.

When the target check code and the final check code match (“Yes” in operation S27), the MTO operation may be performed on the layout data GDS in operation S28.

When the target check code and the final check code do not match (“No” in operation S27), the target ROM code may be updated to the final ROM code in operation S29, and operation S21 to operation S27 may be performed again on the updated target ROM code.

That is, the netlist data CDL and the layout data GDS of the mask ROM may be generated using the final ROM code (S21), a target check code may be generated on the basis of the final ROM code (S22), and the target check code may be inserted into the netlist data CDL of the mask ROM (S23). The netlist data CDL and the layout data GDS of the semiconductor device may be corrected on the basis of the netlist data CDL and the layout data GDS of the mask ROM (S24), and LVS verification of the netlist data CDL and the layout data GDS of the semiconductor device may be performed (S25). Thereafter, a final check code generated using the final ROM code may be generated (S26), and whether the final check code matches the target check code included in the netlist data CDL may be verified (S27).

In some example embodiments, even when the layout data GDS is not analyzed using a layout design tool, it may be verified whether the final ROM code is reflected in the layout data GDS. Accordingly, versatility of the method of verifying the mask ROM layout may be improved, and a verification speed may be improved. Also, when the final ROM code is not reflected in the layout data GDS, the layout data GDS may be corrected before MTO, such that the cost for correcting the error may be reduced.

FIG. 6 illustrates a method of manufacturing a semiconductor device according to the example in which a target ROM code is inserted into the netlist data CDL of the semiconductor device, but the present disclosure is not limited thereto. For example, a layout data GDS may primarily include binary data which may be interpreted using a layout design tool, but may further provide a text region to store text data which may be decoded without using a layout design tool.

In some example embodiments, the target check code may be inserted into the text region of the layout data GDS of the mask ROM, and the target check code may be inserted into the text region of the layout data GDS of the semiconductor device generated based on the layout data GDS of the mask ROM. Also, to verify whether the final ROM code matches the target ROM code, whether the final check code generated on the basis of the final ROM code matches the target check code inserted into the layout data GDS of the semiconductor device may be verified.

In some embodiments, the final ROM code used to generate the final check code (operation S26) may be generated in an operation performed concurrently with the generating the first netlist data and the first layout data (operation S24) and/or the performing of the LVS verification (operation S25).

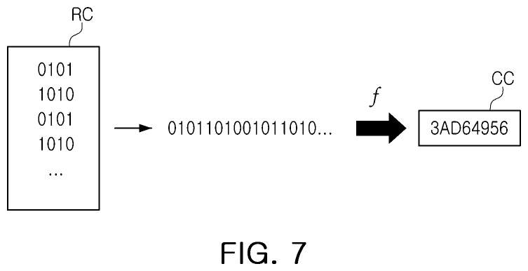

FIG. 7 is a diagram illustrating a method of generating a check code according to some example embodiments.

FIG. 7 illustrates an example of generating check code CC by performing check code generation computation using a check code generation function f on a ROM code RC. The ROM code RC may be data to be stored in the mask ROM and may include a series of bits. FIG. 7 illustrates the ROM code RC in a format sorted according to address and data bandwidth. The check code generation function f may guarantee and produce the same output value for the same input value, and may be similar to a hash function. Also, even when the input value changes slightly, the output value may change significantly.

Even when the ROM code RC arranged in a predetermined format may include space characters in addition to “0” and “1,” the output value may vary significantly, and accordingly, the check code CC may be generated by performing check code generation computation using only binary values from the ROM code RC.

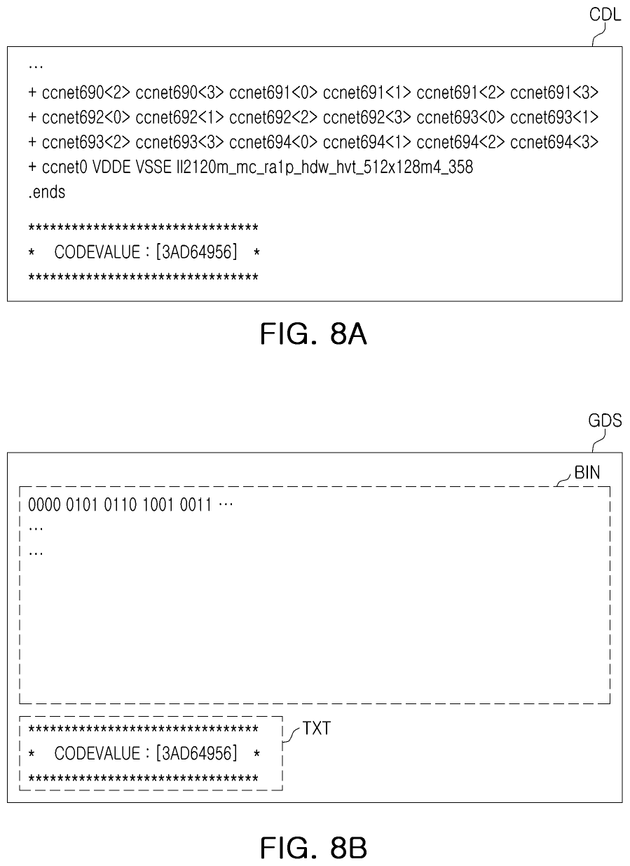

FIG. 8A is a diagram illustrating a netlist data into which a check code is inserted according to some example embodiments. FIG. 8B is a diagram illustrating a layout data into which a check code is inserted according to some example embodiments.

FIG. 8A illustrates netlist data into which a target check code is inserted.

As described with reference to FIG. 4, netlist data CDL may include text data. Referring to FIG. 8A, target check code CODEVALUE may be inserted into netlist data CDL in a text format. The target check code CODEVALUE may be inserted into the netlist data CDL without using a specific layout design tool, and the target check code CODEVALUE may be verified.

The semiconductor device may include a plurality of masks ROM, and the netlist data CDL of the semiconductor device may include netlist data for the plurality of masks ROM. A plurality of target check codes for the plurality of masks ROM, respectively, may be inserted into the netlist data CDL of the semiconductor device. The target check codes may be inserted into the portion corresponding to the masks ROM in the netlist data CDL, or may be inserted into an arbitrarily designated portion.

FIG. 8B illustrates layout data into which a target check code is inserted.

The layout data GDS may include a binary region BIN and a text region TXT. Binary data included in the binary region BIN may not be decoded without a layout design tool, while text data included in the text region TXT may be decoded and corrected without a layout design tool.

In example embodiments, the target check code CODEVALUE may be inserted into the text region TXT of the layout data GDS. When the layout data GDS of the semiconductor device includes layout data for a plurality of masks ROM, a plurality of target check codes for the masks ROM, respectively, may be inserted in the text region TXT.

The example embodiments may be applied to the generation of netlist data and layout data of the mask ROM using a ROM code, and also to the manufacturing of a semiconductor device using netlist data and layout data of the mask ROM obtained externally.

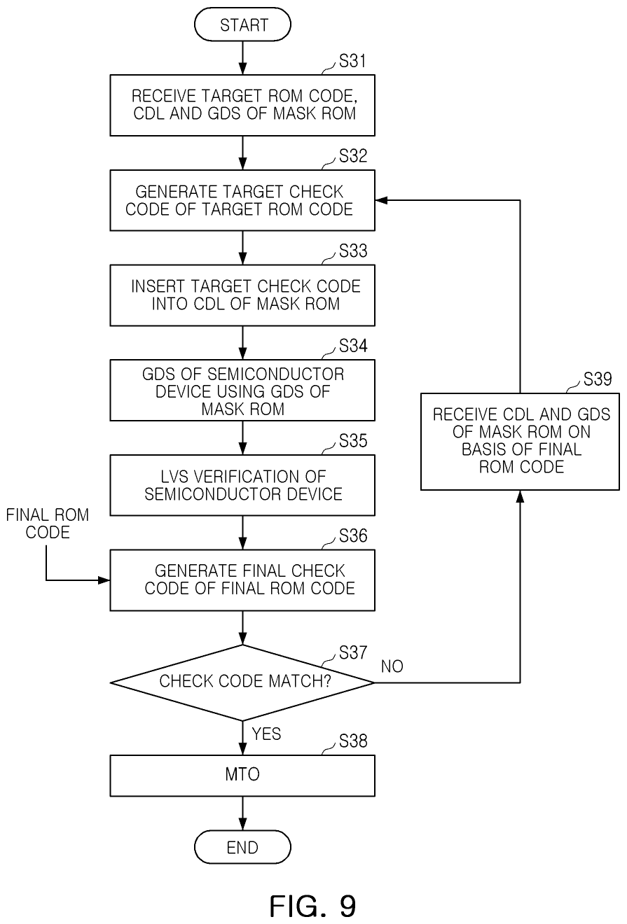

FIG. 9 is a flowchart illustrating a method of manufacturing a semiconductor device according to some example embodiments.

In operation S31, the target ROM code, the netlist data CDL and the layout data GDS of the mask ROM may be received. For example, instead of directly generating the netlist data CDL and the layout data GDS of the mask ROM using the target ROM code received from a customer, the layout of a semiconductor device may be designed by introducing the netlist data CDL and the layout data GDS of the mask ROM designed by a third party designer.

In operation S32, a target check code may be generated by performing check code generation computation on the received target ROM code.

In operation S33, the target check code may be inserted into the netlist data CDL or the layout data GDS of the mask ROM. As described with reference to FIGS. 8A and 8B, the text region of the netlist data CDL or the layout data GDS may be corrected without using a layout design tool, such that a target check code may also be inserted into the netlist data CDL and the layout data GDS received from a third party designer.

Operation S34 to operation S38 may be the same as operation S24 to operation S28 described with reference to FIG. 6. For example, the netlist data CDL and the layout data GDS of the semiconductor device may be generated using the netlist data CDL and the layout data GDS of the mask ROM (S34), and once LVS verification of the netlist data CDL and the layout data GDS of the semiconductor device is completed (S35), the final check code may be generated using the final ROM code received from the customer (S36), and whether the target check code matches the final check code may be compared (S37). When the target check code matches the final check code, an MTO operation may be performed on the layout data GDS of the semiconductor device (S38).

When the target check code does not match the final check code, in operation S39, the netlist data CDL and the layout data GDS of the mask ROM for the final ROM code may be obtained from a third party designer, and the target ROM code may be replaced with the final ROM code and operation S32 to operation S37 may be repeatedly performed. For example, in the netlist data CDL and the layout data GDS of a semiconductor device, the netlist data CDL and the layout data GDS of the existing mask ROM may be replaced with the netlist data CDL and the layout data GDS of the mask ROM for the final ROM code. Also, the target check code stored in the netlist data CDL may be replaced with the final check code.

A method of manufacturing a semiconductor device and a method of verifying the layout of mask ROM may be performed by a processor using data stored in a computer-readable storage medium.

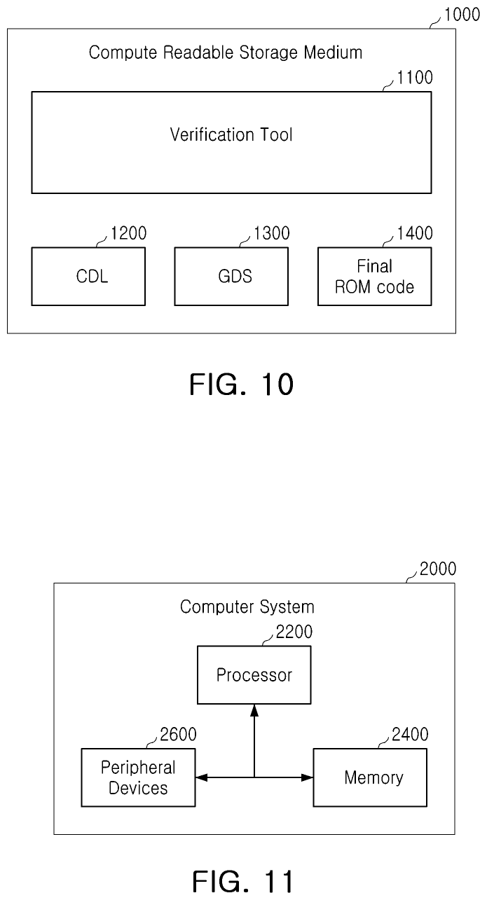

FIG. 10 is a diagram illustrating a storage medium according to some example embodiments.

Storage medium 1000 may be or may include a storage medium which may be read by a computer while being used to provide instructions and data to the computer. For example, the storage medium 1000 may include magnetic or optical media such as a disk, tape, CD-ROM, DVD-ROM, CD-R, CD-RW, DVD-R, DVD-RW, RAM, ROM, a volatile or non-volatile memory such as RAM, ROM, flash memory, a non-volatile memory accessible via USB interface, and/or a microelectromechanical system (MEMS). A computer-readable storage medium may be insertable into a computer, may be integrated within a computer, and/or may be coupled to a computer through a communication medium such as a network and/or wireless link.

Referring to FIG. 10, the storage medium 1000 may store a verification tool 1100, netlist data 1200, layout data 1300 and a final ROM code 1400.

The verification tool 1100 may include instructions for performing a method of verifying the layout of the mask ROM. For example, the verification tool 1100 may include instructions for performing verify code generation computation and computation for comparing a target ROM code with a final ROM code.

The netlist data 1200 may include information indicating a circuit structure included in a semiconductor device. The layout data 1300 may include information indicating the size and the position of objects on a substrate. The final ROM code 1400 may include data to be stored in the mask ROM and may be provided by a customer to be supplied with the semiconductor device.

In some example embodiments, the verification tool 1100 may support a plurality of commands for verifying the layout of the mask ROM. For example, the verification tool 1100 may support a check code creation command, a check code insertion command, and a check code comparison command.

When the check code generation command and the ROM code are input, the verification tool 1100 may output the check code of the ROM code. When the check code insertion command, the netlist data 1200 and the check code are input, the verification tool 1100 may output the netlist data 1200 to which the check code is inserted. Also, when the check code comparison command, the netlist data 1200 and the check code are input, the verification tool 1100 may output the result of comparing the target check code included in the netlist data 1200 with the input check code.

FIG. 11 is a diagram illustrating a computer system according to some example embodiments.

Referring to FIG. 11, the computer system 2000 may include a processor 2200, memory 2400, and various peripheral devices 2600. The processor 2200 may be connected to the memory 2400 and the peripheral devices 2600.

The processor 2200 may be configured to execute instructions for performing one of the methods described above. In some example embodiments, the processor 2200 may execute an instructions set (e.g., intel architecture-32 (IA-32), 64 bit extended IA-32, x86-64, PowerPC, Sparc, MIPS, ARM, IA-64, or the like). Also, the computer system 2000 may include one or more processors.

The processor 2200 may be connected to the memory 2400 and the peripheral devices 2600 in a predetermined manner. For example, the processor 2200 may be connected to the memory 2400 and/or the peripheral devices 2600 through various interconnections. Also, one or more bridge chips may be used to connect these components while creating multiple connections between the processor 2200, the memory 2400 and the peripheral devices 2600.

The memory 2400 may include a predetermined type of memory system. For example, the memory 2400 may include DRMA, DDR SDRAM, RDRAM, or the like. A memory controller may be included to interface to the memory 2400, and/or the processor 2200 may include the memory controller. The memory 2400 may store instructions for performing the method of generating the layout of an integrated circuit described above and data processed by the processor 2200.

The peripheral devices 2600 may include hardware devices which may be included in or combined with the computer system 2000, such as a storage device or an input/output devices (video hardware, audio hardware, user interface devices, networking hardware, or the like.)

In some example embodiments, a method of verifying whether the layout of the mask ROM reflects the final ROM code to be stored in the mask ROM even without using a layout design tool may be automated by the computer system 2000. Accordingly, the automated method of verifying the mask ROM may be used universally, regardless of the type or version of the layout design tool used for semiconductor device layout designing. Also, it may be verified whether the layout of the mask ROM reflects the final ROM code relatively quickly and without analyzing the layout pattern of the mask ROM bit by bit.

According to the aforementioned example embodiments, whether the layout of the mask ROM conforms to the ROM code may be verified even without using a layout design tool to analyze the layout of the mask ROM. Accordingly, versatility of the mask ROM layout analysis method may be improved.

Also, whether the layout of the mask ROM conforms to the ROM code may be verified relatively quickly.

While some example embodiments have been illustrated and described above, those skilled in the art will appreciate that modifications and variations could be made without departing from the scope of the present disclosure as defined by the appended claims.

What is claimed is:

1. A method of manufacturing a semiconductor device, the method comprising:
generating a target check code by performing a target code generation computation on a target ROM code;
generating first netlist data and first layout data of a semiconductor device including a mask ROM storing the target ROM code;
inserting the target check code into the first netlist data;
performing a layout-versus-schematic (LVS) verification of the first netlist data and the first layout data, resulting in verified first netlist data;
generating a final check code by performing the target code generation computation on a final ROM code of the mask ROM;
determining whether the target check code stored in the verified first netlist data matches the final check code; and
performing a mask tape-out operation (MTO) of the first layout data when the target check code matches the final check code.

2. The method of claim 1, further comprising:
correcting the first netlist data and the first layout data on a basis of the final ROM code and replacing the target check code stored in the first netlist data with the final check code, when the target check code and the final check code are different.

3. The method of claim 1, further comprising:
generating the final ROM code,
wherein the generating of the final ROM code is performed concurrently with the generating the first netlist data and the first layout data or the performing the LVS verification.

4. The method of claim 3, wherein the target ROM code is a random binary code.

5. The method of claim 1, wherein the generating of the first netlist data and the first layout data of a semiconductor device including the mask ROM storing the target ROM code includes:
generating second netlist data and second layout data of the mask ROM generated by inputting the target ROM code into a memory generator; and
generating the first netlist data including the second netlist data and the first layout data including the second layout data.

6. The method of claim 5, further comprising:
generating third netlist data and third layout data by inputting the final ROM code into the memory generator when the target check code and the final check code are different;
replacing the second netlist data included in the first netlist data with the third netlist data and replacing the second layout data included in the first layout data with the third layout data; and
replacing the target check code stored in the first netlist data with the final check code.

7. The method of claim 1, wherein the generating the first netlist data and the first layout data of a semiconductor device including the mask ROM storing the target ROM code includes:
receiving second netlist data and second layout data of the mask ROM together with the target ROM code from an external source; and
generating the first netlist data including the second netlist data and the first layout data including the second layout data.

8. The method of claim 7, further comprising:
obtaining third netlist data and third layout data together with the final check code from an external source when the target check code and the final check code are different;
replacing the second netlist data included in the first netlist data with the third netlist data and replacing the second layout data included in the first layout data with the third layout data; and
replacing the target check code stored in the first netlist data with the final check code.

9. The method of claim 1, wherein the first netlist data is text data, and wherein the first layout data is binary data.

10. The method of claim 1,
wherein the first netlist data includes circuit description language (CDL) data, and
wherein the first layout data includes at least one of a graphic design system (GDS) and a GDSII data.

11. The method of claim 1, wherein the generating the target check code by performing target code generation computation on a target ROM code includes performing target code generation computation using only binary values of the target ROM code when the target ROM code includes binary values and characters other than binary values.

12. The method of claim 1, wherein the target code generation computation includes hash function computation.

13. The method of claim 1,
wherein the semiconductor device includes a plurality of masks ROM in which plurality of target ROM codes are stored, respectively, and
wherein the generating the target check code and the inserting the target check code into the first netlist data are performed on each of the plurality of target ROM codes.

14. A method of manufacturing a semiconductor device, the method comprising:
generating a target check code by performing target code generation computation on a target ROM code;
generating first netlist data and first layout data of a semiconductor device including a mask ROM storing the target ROM code;
inserting the target check code into a text region included in the first layout data;
generating a final check code by receiving a final ROM code of the mask ROM and performing the target code generation computation on the final ROM code;
determining whether the target check code inserted in the first layout data matches the final check code; and
performing a mask tape-out (MTO) operation on the first layout data when the target check code matches the final check code.

15. The method of claim 14, wherein the first layout data further includes a binary region that defines a layout of the semiconductor device.

16. The method of claim 14, further comprising:
performing layout-versus-schematic (LVS) verification of the first netlist data and the first layout data before performing the verifying whether the target check code matches the final check code.

17. A method of verifying a layout of a mask ROM, the method comprising:
inserting a check code generated by performing check code generation computation on a ROM code of the mask ROM into netlist data of the mask ROM;
performing an LVS verification on the netlist data and layout data of the mask ROM; and
comparing a final check code generated by performing check code computation on a final ROM code to be stored in the mask ROM with the check code inserted into the netlist data.

18. The method of claim 17, wherein the inserting the check code into netlist data of the mask ROM includes obtaining netlist data into which the check code is inserted by entering a check code insertion command and the ROM code and the netlist data into a verification tool.

19. The method of claim 17, further comprising:
obtaining the final check code by entering a check code generation command and the final ROM code into a verification tool.

20. The method of claim 17, wherein the comparing of the final check code with a check code inserted into the netlist data includes comparing a check code inserted in the netlist data with the final check code by entering a check code comparison command, the netlist data and the final check code into a verification tool.
